(19) United States
(12) Patent Application Publication
(10) Pub. No.: US 2006/0197078 A1
(43) Pub. Date: Sep. 7, 2006

(54) ORGANIC LIGHT-EMITTING DISPLAY DEVICE HAVING HIGH LIGHT UTILIZATION

(76) Inventor: Tai-Cherng Yu, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,890

(22) Filed: Dec. 8, 2005

(30) Foreign Application Priority Data
Dec. 15, 2004 (CN) 200410077568.X

(51) Int. Cl. H01L 29/08; H01L 35/24; H01L 51/00

(52) U.S. Cl. 257/40

(57) ABSTRACT

An organic light-emitting display device includes a light-emitting layer (10), a light permeable layer (20) and a prismatic film (40). The light permeable layer is positioned on the light-emitting layer, and the prismatic film is placed on the light permeable layer. The prismatic film includes a plurality of prisms (42). In use, light rays emitted from the light-emitting layer travel through the light permeable layer and are refracted by the prisms. This reduces angle of emergency of the emitted light rays and can converge the emitted light rays in the range of effective viewing angles. Thus, almost all the emitted light rays can be utilized thereby enhancing a light utilization of the organic light-emitting display device.

### FIELD OF THE INVENTION

The invention relates generally to organic light-emitting display devices, and more particularly, to an organic light-emitting display device having high light utilization.

### DESCRIPTION OF THE RELATED ART

Organic light-emitting display devices have many excellent performance features, such as simple structure, self illumination, low driving voltage, high brightness, high contrast ratio, short response time, easy to color, wide viewing angle and so on. Therefore, the organic light-emitting display devices are used widely. Referring to FIG. 5, a typical organic light-emitting display device includes a light-emitting layer 1, a light permeable layer 2 and a protection layer 3. The light-emitting layer 1 is positioned between the light permeable layer 2 and the protection layer 60. The light permeable layer 20 includes a light-emitting surface 22. The light permeable layer 20 is generally made of glass. The protection layer 60 is generally a glass or metal plate.

Referring to FIG. 6, the light-emitting layer 1 includes an emitting material layer 16, an anode 12, a cathode 14, a hole transport layer 18 and an electron transport layer 19. The emitting material layer 16 is located between the anode 12 and the cathode 14. The hole transport layer 18 is located between the anode 12 and the emitting material layer 16. The electron transport layer 19 is located between the cathode 14 and the emitting material layer 16. The emitting material layer 16 is made of an organic material. The emitting material layer 16 can be a single mixed layer or multiple pure layers. The anode 12 is made of high work function materials, such as Indium Tin Oxide (ITO), indium zinc oxide (IZO), Indium oxide, zinc oxide, nickel oxide, antimony trioxide and so on. Furthermore, the anode 12 can be also made of doped conductive polymer, such as poly-aniline, polythiophene and so on. The cathode 14 is made of low work function materials, such as calcium (Ca), magnesium (Mg), aluminum (Al), indium (In), lithium (Li) and so on. The hole transport layer 18 is configured for facilitating movement of holes (i.e., positive charges) toward the emitting material layer 16. The electron transport layer 19 is configured for facilitating movement of electrons (i.e., negative charges) toward the emitting material layer 16.

In use, a voltage is applied between the anode 12 and the cathode 14. The voltage is generally a direct current bias and is generally in the range from 2 to 30 volts. This forms an electric field between the anode 12 and the cathode 14. Holes (i.e., positive charges) injected from the anode 12 are driven by the electric field to move through the hole transport layer 18 and reach the emitting material layer 16. At the same time, electrons (i.e., negative charges) injected from the cathode 14 are driven by the electric field to move through the electron transport layer 19 and reach the emitting material layer 16. The electrons meet with and are combined with the holes in the emitting material layer 16. This electron-hole capture results in light emission. The wavelength and color of the light are determined by the organic material of the emitting material layer 12.

Referring to FIG. 7, the light rays α1, α2, α3, α4 emitted from the light-emitting layer 1 travel through the light permeable layer 2. The light rays al, α2, α3, α4 are then refracted and exit from the light-emitting surface 22 of the light permeable layer 2. Due to the wide viewing angle feature of the organic light-emitting display device, the angles of emergency of the emitted light rays α1, α2, α3, α4 are relatively large. Thus, the largest viewing angle θ1 of the organic light-emitting display device is about 180°. However, the light rays having angles of emergency larger than 160° can't be fully utilized and are wasted. Thus, a light utilization of the organic light-emitting display device is relatively low.

What is needed, therefore, is an organic light-emitting display device which has high light utilization.

### SUMMARY OF INVENTION

In one embodiment, an organic light-emitting display device includes a light-emitting layer, a light permeable layer and a prismatic film. The light permeable layer is positioned on the light-emitting layer, and the prismatic film is placed on the light permeable layer. The prismatic film are made of at least one of polyester resin, acrylic resin, fluorinated resin, vinyl chloride resin and polycarbonate resin. The prismatic film includes a plurality of prisms.

The light-emitting layer includes an emitting material layer, an anode, a cathode, a hole transport layer and an electron transport layer. The emitting material layer is located between the anode and the cathode. The hole transport layer is located between the anode and the emitting material layer. The electron transport layer is located between the cathode and the emitting material layer. The emitting material layer is made of an organic material. The emitting material layer can be a single mixed layer or multiple pure layers. The prisms are formed by an imprinting technique, such as a hot-embossing process or a step-and-flash lithography process. A top angle of each prism is in the range from 60° to 120°. In the preferred embodiment, the top angle of each prism is in the range from 70° to 100°. The shape of each prism is selected from the group consisting of triangular prisms, triangular pyramids, anamorphic prisms and curved prisms.

In use, light rays emitted from the light-emitting layer travel through the light permeable layer and are refracted by the prisms. This reduces angles of emergency of the emitted light rays and can converge the emitted light rays in the range of effective viewing angles. Thus, almost all the emitted light rays can be utilized thereby enhancing a light utilization of the organic light-emitting display device.

Other advantages and novel features of the present method will become more apparent from the following detailed description of preferred embodiments when taken in conjunction with the accompanying drawings.

### BRIEF DESCRIPTION OF DRAWINGS

Many aspects of the present organic light-emitting display device can be better understood with reference to the following drawings. The components in the drawings are not necessarily to scale, the emphasis instead being placed upon clearly illustrating the principles of the present organic light-emitting display device.

FIG. 1 is a schematic side view of an organic light-emitting display device in accordance with a preferred embodiment of the present device;

FIG. 2 is a schematic side view of a light-emitting layer of the organic light-emitting display device of FIG. 1;

FIG. 3 is a schematic side view of a prismatic film of the organic light-emitting display device of FIG. 1, showing a light path associated therewith;

FIG. 4 is a schematic side view of an imprinting stamper used for forming the prismatic film of FIG. 3;

FIG. 5 is a schematic side view of a conventional organic light-emitting display device;

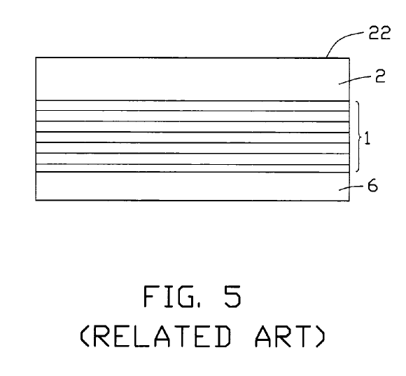

FIG. 6 is a schematic side view of a light-emitting layer of the organic light-emitting display device of FIG. 5; and

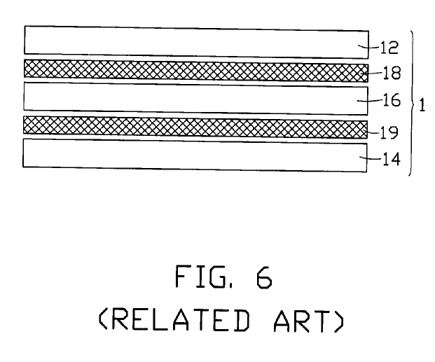

FIG. 7 is similar to FIG. 5, but showing light paths associated with the organic light-emitting display device.

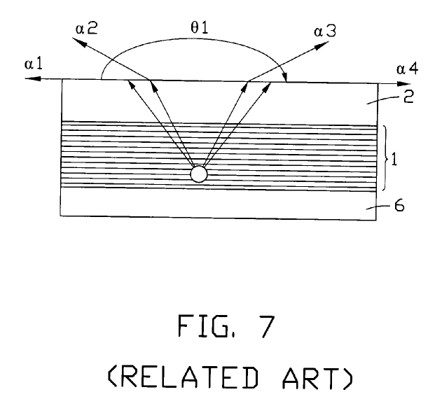

Corresponding reference characters indicate corresponding parts throughout the several views. The exemplifications set out herein illustrate at least one preferred embodiment of the present organic light-emitting display device, in one form, and such exemplifications are not to be construed as limiting the scope of the invention in any manner.

### DETAILED DESCRIPTION

Reference will now be made to the drawings to describe embodiments of the present organic light-emitting display device, in detail.

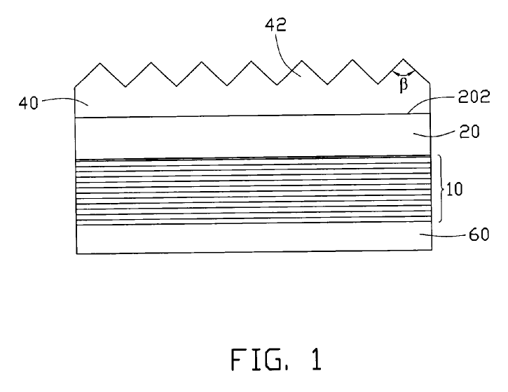

Referring to FIG. 1, an organic light-emitting display device includes a light-emitting layer 10, a light permeable layer 20, a prismatic film 40 and a protection layer 60. The light-emitting layer 10 is positioned between the light permeable layer 20 and the protection layer 60. The light permeable layer 20 includes a light-emitting surface 202. The prismatic film 40 is arranged on the light-emitting surface 202 of the light permeable layer 20. The light permeable layer 20 is generally made of glass. The protection layer 60 is a glass or metal plate.

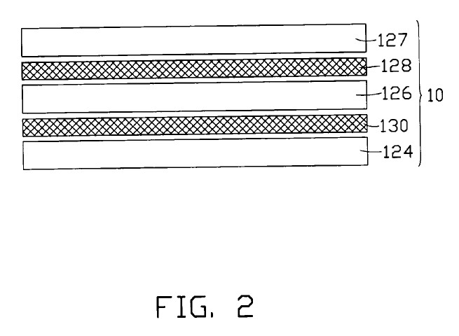

Referring to FIG. 2, the light-emitting layer 10 includes an emitting material layer 126, an anode 127, a cathode 124, a hole transport layer 128 and an electron transport layer 130. The emitting material layer 126 is located between the anode 127 and the cathode 124. The hole transport layer 128 is located between the anode 127 and the emitting material layer 126. The electron transport layer 130 is located between the cathode 124 and the emitting material layer 126. The emitting material layer 126 is made of an organic material. The emitting material layer 126 can be a single mixed layer or multiple pure layers. The anode 127 is made of high work function materials, such as Indium Tin Oxide (ITO), indium zinc oxide (IZO), Indium oxide, zinc oxide, nickel oxide, antimony trioxide and so on. Furthermore, the anode 127 can be also made of doped conductive polymer, such as poly- aniline, polythiophene and so on. The cathode 124 is made of low work function materials, such as calcium (Ca), magnesium (Mg), aluminum (Al), indium (In), lithium (Li) and so on. The hole transport layer 128 is configured for facilitating movement of holes (i.e., positive charges) toward the emitting material layer 126. The electron transport layer 130 is configured for facilitating movement of electrons (i.e., negative charges) toward the emitting material layer 126.

The prismatic film 40 can be a multi-layer prismatic film or a single layer prismatic film. In the preferred embodiment, the prismatic film 40 is a single layer prismatic film. The prismatic film 40 is made of thermoplastic materials. The thermoplastic materials are selected from the group consisting of polyester resin, such as polyethylene terephthalate or polyethylene naphthalate; acrylic resin, such as polymethyl methacrylate or modified polymethyl methacrylate; fluorinated resin, such as polyvinylidene fluoride; vinyl chloride resin, such as vinyl chloride compolyners and polycarbonate resin. In the preferred embodiment, the prismatic film 40 is made of polycarbonate resin. The prismatic film 40 includes a plurality of prisms 42 and a non-patterned surface (not labeled). The non-patterned surface is opposite from the prisms 42 and comes into contact with the light-emitting surface 202 of the light permeable layer 20. The shape of each prism 42 is selected from the group consisting of triangular prisms, triangular pyramids, anamorphic prisms and curved prisms. In the preferred embodiment, the prisms 42 are triangular prisms. A top angle of each prism 42 is in the range from 60° to 120°. In the preferred embodiment, the top angle of each prism 42 is in the range from 70° to 100°.

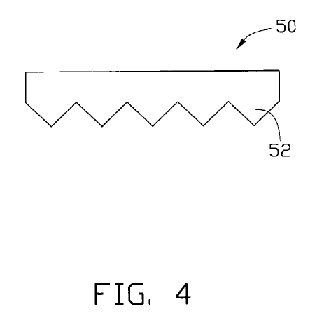

The prismatic film 40 can be formed by an imprinting technique, such as a hot embossing process or a step-and-flash lithography process. In the preferred embodiment, the prismatic film 40 is formed by a hot embossing process. An exemplary hot embossing process is described as follows. Firstly, an imprinting stamper 50 is provided. Referring to FIG. 4, the imprinting stamper 50 including a plurality of triangular prisms 52. Secondly, a polycarbonate resin film is provided. A thickness of the polycarbonate resin film is in the range from 50 to 600 millimeters. In the preferred embodiment, the thickness of the polycarbonate resin film is in the range from 100 to 300 millimeters. Thirdly, the imprinting stamper 50 (specifically the patterned surface thereof) is placed together with the polycarbonate resin film. Then, the imprinting stamper 50 and the polycarbonate resin film are heated and are compressed against each other. This ensures that the patterns of the triangular prisms 52 of the imprinting stamper 50 are almost fully, if not totally, transferred into the polycarbonate resin film. Finally, the imprinting stamper 50 and the polyester resin film are cooled and are separated from each other. This forming the prismatic film 40 having the triangular prisms 42 corresponding to the triangular prisms 52 of the imprinting stamper 50.

In this case, the patterns of the triangular prisms 42 formed on the prismatic film 40 are the product of shapes mirroring those of the triangular prisms 52 of the imprinting stamper 50. Also, while the imprinting stamper 50 is disclosed to be used as a part of a hot embossing process, it is to be understood that any other molding processes (such as a step-and-flash lithography process) incorporating the present imprinting stamper 50 and resulting in the desired triangular prism pattern on thermoplastic materials is considered to be within the scope of the present invention.

In use, a voltage is applied between the anode 127 and the cathode 124. The voltage is generally is a direct current bias and is generally in the range from 2 to 30 volts. This forms an electric field between the anode 127 and the cathode 124. Holes (i.e., positive charges) are driven by the electric field to move through the hole transport layer 128 and reach the emitting material layer 126. At the same time, electrons (i.e., negative charges) are driven by the electric field to move through the electron transport layer 130 and reach the emitting material layer 126. The electrons meet with and are combined with the holes in the emitting material layer 126. This electron-hole capture results in light emission. The wavelength and color of the light are determined by the organic material of the emitting material layer 126.

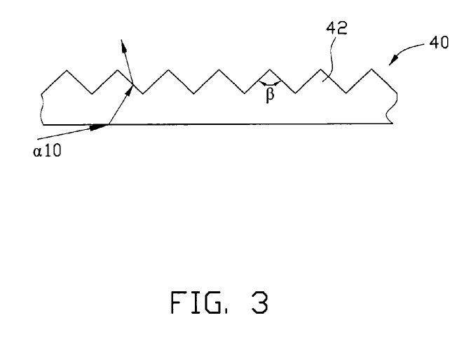

Referring to FIG. 3, one of the light rays (labeled as α10) emitted from the light-emitting layer 10 travels through the light permeable layer 20 and reaches the prismatic film 40. An angle of emergency of the emitted light ray α10 (i.e., an angle of inclination of the emitted light ray α10 relative to a normal of the light-emitting surface 202 of the light permeable layer 20) is about 89°. The light ray α10 is firstly refracted by the non-patterned surface of the prismatic film 40 and then travels in the prismatic film 40. When the refracted light ray α10 reaches the corresponding prism 42, the refracted light ray α10 is further refracted by the corresponding prism 42 and eventually exits therefrom. This reduces the angle of emergency of the emitted light ray α10 and can converge the emitted light ray α10 in the range of effective viewing angles (i.e., equal to or less than 160°). Thus, almost all the emitted light rays can be fully utilized thereby enhancing the light utilization of the organic light-emitting display device.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. An organic light-emitting display device comprising:
a light-emitting layer;
a light permeable layer positioned on the light-emitting layer; and
a prismatic film provided on the light permeable layer, the prismatic film having a plurality of prisms.

2. The organic light-emitting display device as claimed in claim 1, wherein the light-emitting layer comprises an anode, a cathode opposite to the anode and an emitting material layer located between the anode and the cathode.

3. The organic light-emitting display device as claimed in claim 2, wherein the light-emitting layer comprises a hole transport layer located between the anode and the emitting material layer, and an electron transport layer located between the cathode and the emitting material layer.

4. The organic light-emitting display device as claimed in claim 1, wherein the prisms are formed by an imprinting process.

5. The organic light-emitting display device as claimed in claim 4, wherein the prisms are formed by a hot-embossing process.

6. The organic light-emitting display device as claimed in claim 4, wherein the prisms are formed by a step-and-flash lithography process.

7. The organic light-emitting display device as claimed in claim 1, wherein a top angle of a cross-section of each prism is in the range from 60° to 120°.

8. The organic light-emitting display device as claimed in claim 7, wherein the top angle of the prism is in the range from 70° to 100°.

9. The organic light-emitting display device as claimed in claim 1, wherein the shape of each prism is selected from the group consisting of triangular prisms, triangular pyramids, anamorphic prisms and curved prisms.

10. The organic light-emitting display device as claimed in claim 1, wherein the prismatic film is comprised of a material selected from the group consisting of polyester resin, acrylic resin, fluorinated resin, vinyl chloride resin and polycarbonate resin.

11. The organic light-emitting display device as claimed in claim 1, wherein the prismatic film is a single layer prismatic film.

12. The organic light-emitting display device as claimed in claim 1, wherein the organic light-emitting display device comprises a protection layer brought into contact with the light-emitting layer.

13. An organic light-emitting display device comprising:
an organic light-emitting device having a light-emitting surface; and
a prismatic film located on the light-emitting surface, the prismatic film having a plurality of prisms.

14. The organic light-emitting display device as claimed in claim 13, wherein the prisms are formed by one of a hot-embossing process and a step-and-flash lithography process.

15. The organic light-emitting display device as claimed in claim 13, wherein a top angle of a cross-section of each prism is in the range from 60° to 120°.

16. The organic light-emitting display device as claimed in claim 15, wherein the top angle of the prism is in the range from 70° to 100°.

17. The organic light-emitting display device as claimed in claim 13, wherein the shape of each of the prisms is selected from the group consisting of triangular prisms, triangular pyramids, anamorphic prisms and curved prisms.

18. The organic light-emitting display device as claimed in claim 13, wherein the prismatic film is comprised of a material selected from the group consisting of polyester resin, acrylic resin, fluorinated resin, vinyl chloride resin and polycarbonate resin.

19. The organic light-emitting display device as claimed in claim 13, wherein the prismatic film is a single layer prismatic film.
